(19) United States
(12) Patent Application Publication
(10) Pub. No.: US 2023/0389195 A1
(43) Pub. Date: Nov. 30, 2023

(54) ELECTRONIC COMPONENT

(71) Applicant: NIDEC COPAL ELECTRONICS CORPORATION, Tokyo (JP)

(72) Inventor: Kazuto Ohtake, Sano-shi (JP)

(73) Assignee: NIDEC COPAL ELECTRONICS CORPORATION, Tokyo (JP)

(21) Appl. No.: 18/366,837

(22) Filed: Aug. 8, 2023

Related U.S. Application Data
(63) Continuation of application No. PCT/JP21/47863, filed on Dec. 23, 2021.

(30) Foreign Application Priority Data
Feb. 8, 2021 (JP) 2021-018167

(51) Int. Cl. H05K 5/00; H05K 5/03; H05K 5/02

(52) U.S. Cl. CPC H05K 5/0069; H05K 5/03; H05K 5/0204

(57) ABSTRACT

An electronic component includes a pair of first engaging parts and a pair of second engaging parts. Both of the pair of first engaging parts are arranged at side surfaces of a case parallel to each other in opposition to each other. Each of the pair of second engaging parts is arranged adjacent to each of the pair of first engaging parts. Each of the first engaging parts includes a first arm and first protrusion, each of the second engaging parts includes a second arm and second protrusion, and a length of the second protrusion is longer than a length of the first protrusion.

### CROSS-REFERENCE TO RELATED APPLICATIONS

This application is a continuation of International Application No. PCT/JP2021/047863, filed on Dec. 23, 2021, and based upon and claiming the benefit of priority from prior Japanese Patent Application No. 2021-018167, filed on Feb. 8, 2021, the entire contents of all of which are incorporated herein by reference.

### FIELD

Embodiments described herein relate generally to an electronic component such as a pressure sensor or the like.

### BACKGROUND

In general, in an electronic component, a circuit board on which circuit components are arranged is accommodated in a case. The circuit board is positioned and retained by protrusions provided on both sides of the case (see, for example, Patent Literature 1 (JP 2003-229682 A)).

### SUMMARY

In the case where a part of the circuit board is held by the protrusions provided on the case, there is sometimes a case where a tolerance is allowed for the thickness of the circuit board as an allowable error. When the thickness of the circuit board is thick within the range of the tolerance, the protrusions are largely deformed, and hence it is not possible to sufficiently hold the circuit board by means of the protrusions. Moreover, when the protrusions are largely deformed, it is necessary to make the case larger in consideration of the maximum deformation amount of each protrusion. On the other hand, when the thickness of the circuit board is thin within the range of the tolerance, a gap is created between the circuit board and each of the protrusions, and it is not possible to sufficiently hold the circuit board by means of the protrusions.

One embodiment described herein aims to provide an electronic component capable of securely holding a circuit board in which a tolerance is allowed for the thickness thereof.

An electronic component of the present embodiment comprising a rectangular case including a rectangular opening, the opening being covered with a board; a pair of first engaging parts arranged in opposition to each other at side surfaces of the case parallel to each other; and a pair of second engaging parts each arranged adjacent to the pair of first engaging parts at each of the side surfaces of the case, wherein each of the pair of first engaging parts includes a first arm, the first arm includes a first end and a second end, the first end is provided at the case, and the second end includes a first protrusion protruded from the lateral face side of the board toward the surface thereof, each of the pair of second engaging parts includes a second arm, the second arm includes a third end and a fourth end, the third end is provided at the case, and the fourth end includes a second protrusion protruded from the lateral face side of the board toward the surface thereof, and a length of the second protrusion in a direction along the surface of the board is greater than a length of the first protrusion.

Additional objects and advantages of the disclosure will be set forth in the description which follows, and in part will be obvious from the description, or may be learned by practice of the disclosure. The objects and advantages of the disclosure may be realized and obtained by means of the instrumentalities and combinations particularly pointed out hereinafter.

### DRAWINGS

The accompanying drawings, which are incorporated in and constitute a part of the specification, illustrate embodiments of the disclosure, and together with the general description given above and the detailed description of the embodiments given below, serve to explain the principles of the disclosure.

FIG. 1 is a perspective view showing an electronic component according to the embodiment;

FIG. 2 is a perspective view showing a part of FIG. 1 in an extracting manner;

FIG. 3 is a top view of FIG. 2;

FIG. 4 is a side view showing a part of FIG. 3 along line IV-IV;

FIG. 5 is a side view showing an operation of FIG. 4; and

FIG. 6 is a side view showing an operation different from FIG. 5.

### DETAILED DESCRIPTION

An embodiment of the present disclosure will be described below with reference to the accompanying drawings. Elements like or similar to those disclosed in the above embodiment are denoted by similar reference numerals.

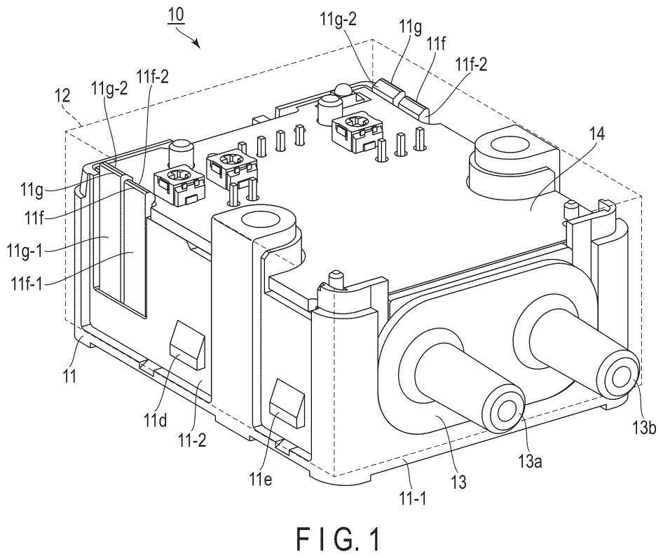

FIG. 1 shows an electronic component to which this embodiment is applied, for example, a pressure sensor. This embodiment is not limited to the pressure sensor and can be applied to various electronic components and electronic devices.

As shown in FIGS. 1 to 3, a rectangular case 11 includes a pair of first side surfaces 11-1 parallel to each other, a pair of second side surfaces 11-2 orthogonal to the first side surfaces 11-1 and parallel to each other, and bottom 11-3, and further includes an opening 11a at an upper part thereof opposed to the bottom. The pair of first side surfaces 11-1 each includes a first cutout part 11b and second cutout part 11c.

To the first cutout part 11b, a plate 13 is attached. The plate 13 includes, for example, an inlet 13a and an outlet 13b of a gas to be measured. To the second cutout part 11c, a connector (not shown) is attached. The connector includes a plurality of terminals (not shown), and the plural terminals are connected to a pressure sensor and electronic circuit which are not shown and are arranged inside the case 11.

The opening 11a of the case 11 is covered with a printed circuit board (hereinafter referred to as a board) 14. Inside the case 11, a pressure sensor is provided, and the pressure sensor is connected to the inlet 13a and the outlet 13b with, for example, pipes (not shown).

Furthermore, the first side surfaces 11-1, second side surfaces 11-2, and board 14 are covered with a cover 12. The cover 12 is engaged by a plurality of protrusions 11d and 11e provided on the second side surfaces 11-2.

On the second side surfaces 11-2 of the case 11, a pair of first engaging parts 11f and a pair of second engaging parts 11g each configured to fasten the board 14 are provided. Both of the pair of first engaging parts 11f are arranged in opposition to each other at the second side surfaces 11-2 parallel to each other, and both of the pair of second engaging parts 11g are arranged adjacent to the first engaging parts 11f and in opposition to each other at the second side surfaces 11-2 parallel to each other.

As shown in FIG. 1, each of the first engaging parts 11f includes a first arm 11f-1 and hook-like first protrusion 11f-2, and each of the second engaging parts 11g includes a second arm 11g-1 and hook-like second protrusion 11g-2. A first end of the first arm 11f-1 is provided at a part of the second side surface 11-2 and, at a second end thereof, the first protrusion 11f-2 is provided. A first end of the second arm 11g-1 is provided at a part of the second side surface 11-2 and, at a second end of the second arm 11g-1, the second protrusion 11g-2 is provided.

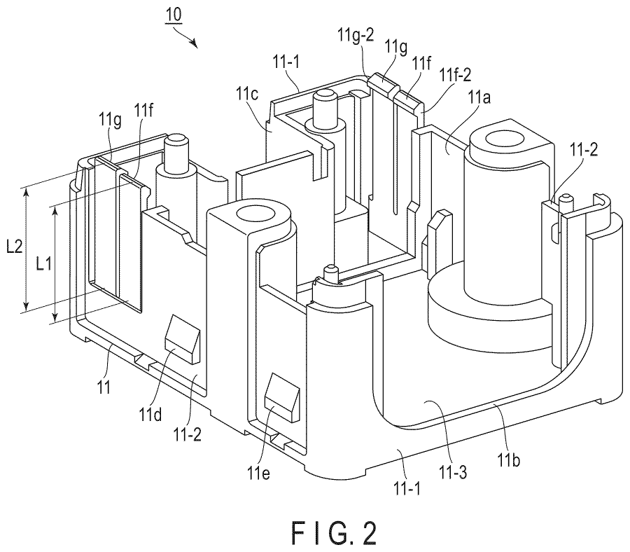

As shown in FIG. 2, the first arm 11f-1 has a first length L1 and second arm 11g-1 has a second length L2 longer than the first length L1.

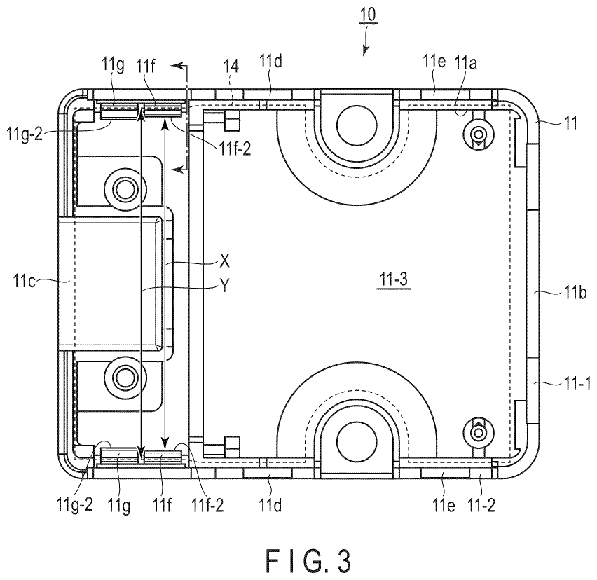

As shown in FIG. 1 and FIG. 3, the first protrusion 11f-2 is protruded in a direction approximately orthogonal to the longitudinal direction of the first arm 11f-1, and second protrusion 11g-2 is also protruded in a direction approximately orthogonal to the longitudinal direction of the second arm 11g-1. A tip of each of the first protrusion 11f-2 and second protrusion 11g-2 has, for example, approximately an arc-like shape and, tip of the second protrusion 11g-2 is protruded beyond the tip of the first protrusion 11f-2. Although the shape of the first protrusion 11f-2 is similar to the shape of the second protrusion 11g-2, the shape of the first protrusion 11f-2 may also be different from the shape of the second protrusion 11g-2.

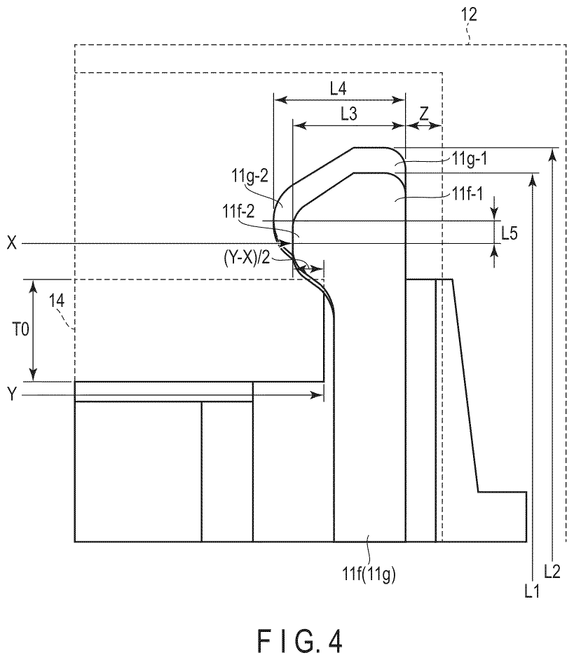

FIG. 4 shows an enlarged view of the first protrusion 11f-2 and second protrusion 11g-2. The length of the first protrusion 11f-2 in the direction along the surface of the board 14 is L3, the length of the second protrusion 11g-2 is L4, and L4 is longer than L3 (L3<L4).

Further, in the thickness direction of the board 14, the position of the tip of the first protrusion 11f-2 is lower than the position of the tip of the second protrusion 11g-2. A difference between the position of the tip of the first protrusion 11f-2 and position of the tip of the second protrusion 11g-2 is indicated by a distance L5. Although the distance L5 is equal to L2-L1 (L5=L2−L1), the distance L5 may also be different from L2−L1.

Between each of the first arm 11f-1 and second arm 11g-1 and inner surface of the cover 12, a gap is provided. The distance of the gap is indicated by Z. The first arm 11f-1 and second arm 11g-1 can move within the range of the gap.

Assuming that the distance between the pair of first protrusions 11f-2 opposed to each other is X, assuming that the width of the board 14 arranged between the pair of first engaging parts 11f and between the pair of second engaging parts 11g is Y, and assuming that the distance between each of the first engaging part 11f and second engaging part 11g and inner surface of the cover 12 is Z, the relationship among X, Y, and Z is indicated by the following formula as follows.

(Y−X)/2<Z

The width Y of the board 14 is equal to or slightly less than the distance between the pair of first arms 11f-1 (the pair of second arms 11g-1).

Regarding the configuration described above, the operation of each of the first engaging part 11f and second engaging part 11g will be described below.

(Case of Thin Board)

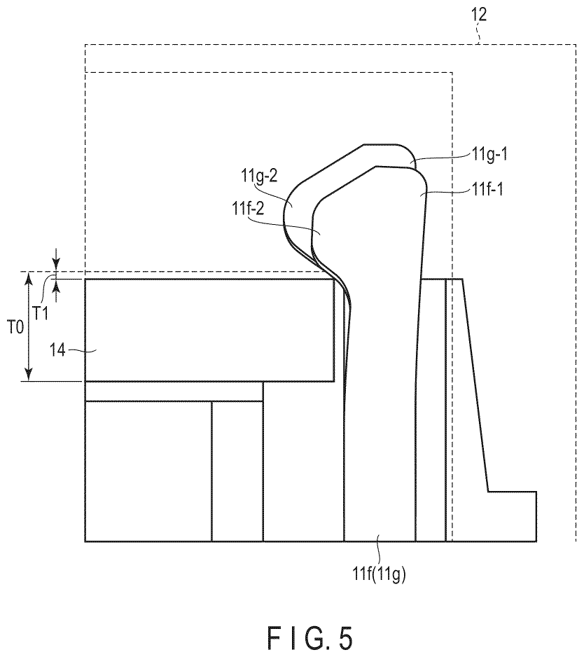

As shown in FIG. 5, in the case where the thickness of the board 14 is less than the standard thickness TO shown in FIG. 4 by T1 within the range of the tolerance, the board 14 is held by the pair of first engaging parts 11f that contact the corners of the board 14. Specifically, the first protrusion 11f-2 of each of the pair of first engaging parts 11f is positioned at a part ranging from the lateral face side of the board 14 to a position on the surface of the board 14 and basal part (lower part) of the first protrusion 11f-2 is in contact with the corner part of the board 14. For this reason, the first arms 11f-1 are slightly deformed toward the inner surface of the cover 12 and board 14 is pushed toward the bottom of the case 11 by the first protrusions 11f-2 owing to the elasticity of the first arms 11f-1.

On the other hand, the second protrusions 11g-2 of the second engaging parts 11g do not come into contact with the surface of the board 14. For this reason, the second arms 11g-1 are hardly deformed.

(Case of Thick Board)

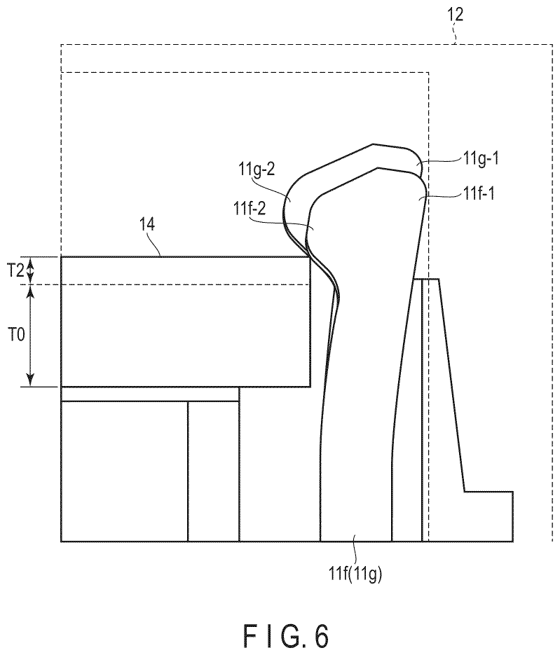

As shown in FIG. 6, in the case where the thickness of the board 14 is greater than the standard thickness TO shown in FIG. 4 by T2 within the range of the tolerance, the board 14 is held by the pair of second engaging parts 11g that contact the corner parts of the board 14. Specifically, the second protrusion 11g-2 of each of the pair of second engaging parts 11g is positioned at a part ranging from the lateral face side of the board 14 to a position on the surface of the board 14 and basal part (lower part) of the second protrusion 11g-2 is in contact with the corner of the board 14. For this reason, the second arms 11g-1 are slightly deformed toward the inner surface of the cover 12 and board 14 is pushed toward the bottom of the case 11 by the second protrusions 11g-2 owing to the elasticity of the second arms 11g-1.

On the other hand, the tip of the first protrusion 11f-2 of each of the first engaging parts 11f is in contact with the corner or lateral face of the board 14. For this reason, when the thickness of the board 14 is large within the range of the tolerance, it is not possible to press the board 14 toward the bottom of the case 11 by means of the first protrusions 11f-2. At this time, the first arms 11f-1 are deformed toward the inner surface of the cover 12 to a greater extent than the second arms 11g-1. However, the length L3 of the first protrusion 11f-2 is less than the length L4 of the second protrusion 11g-2 and, furthermore, the length L1 of the first arm 11f-1 is shorter than the length L2 of the second arm 11g-1. For this reason, it is possible to make the deformation amount of the first arm 11f-1 fall within the range of the distance Z of the gap between each of the first arm 11f-1 and second arm 11g-1 and inner surface of the cover 12 of the case where no board 14 is provided.

It should be noted that in the case where the thickness of the board 14 is slightly larger within the range of the tolerance (in the case where the error of the thickness is less than T2), the board 14 is held by both the first protrusion 11f-2 and second protrusion 11g-2.

### Advantageous Effects of Embodiment

According to the embodiment described above, a case 11 includes a pair of first engaging parts 11f and a pair of second engaging parts 11g, each of the first engaging parts 11f includes a first arm 11f-1 and first protrusion 11f-2, and each of the second engaging pars 11g includes a second arm 11g-1 and second protrusion 11g-2. The second arm 11g-1 is longer than the first arm 11f-1, and second protrusion 11g-2 is longer than the first protrusion 11f-2. For this reason, when the thickness of the board 14 is thin within the range of the tolerance, the board 14 is held by the first protrusions 11f-2 and, when the thickness of the board 14 is thick within the range of the tolerance, the board 14 is held by the second protrusions 11g-2 or by the second protrusions 11g-2 and first protrusions 11f-2. Therefore, according to the embodiment described above, even when the thickness varies within the range of the tolerance, it is possible to securely hold the board 14.

Moreover, according to the embodiment described above, the length of the first protrusion 11f-2 is shorter than the length of the second protrusion 11g-2, and hence when the thickness of the board 14 is thick within the range of the tolerance, the deformation amount of the first arm 11f-1 can be suppressed. Furthermore, the length of the first arm 11f-1 is shorter than the length of the second arm 11g-1. For this reason, it is possible to reduce the distance Z of the gap between each of the first arm 11f-1 and second arm 11g-1 and inner surface of the cover 12, and prevent the cover 12 and electronic component 10 from growing in size.

Additional advantages and modifications will readily occur to those skilled in the art. Therefore, the disclosure in its broader aspects is not limited to the specific details and representative embodiments shown and described herein. Accordingly, various modifications may be made without departing from the spirit or scope of the general inventive concept as defined by the appended claims and their equivalents.

What is claimed is:

1. An electronic component comprising:
a rectangular case including a rectangular opening, the opening being covered with a board;
a pair of first engaging parts arranged in opposition to each other at side surfaces of the case parallel to each other; and
a pair of second engaging parts each arranged adjacent to the pair of first engaging parts at each of the side surfaces of the case, wherein
each of the pair of first engaging parts includes a first arm, the first arm includes a first end and a second end, the first end is provided at the case, and the second end includes a first protrusion protruded from the lateral face side of the board toward the surface thereof,
each of the pair of second engaging parts includes a second arm, the second arm includes a third end and a fourth end, the third end is provided at the case, and the fourth end includes a second protrusion protruded from the lateral face side of the board toward the surface thereof, and
a length of the second protrusion in a direction along the surface of the board is greater than a length of the first protrusion.

2. The electronic component of claim 1, further comprising a cover attached to the case and covering the board, the first engaging parts and the second engaging parts, wherein
assuming that a distance between the pair of first protrusions opposing to each other is X,
that a width of the board arranged between the pair of first engaging parts and between the pair of second engaging parts is Y, and
that a distance between each of the first engaging part and the second engaging part and an inner surface of the cover is Z,
a relationship among X, Y, and Z is the following formula:
(Y−X)/2<Z.

3. The electronic component of claim 1, wherein
the first arm possesses a first length and the second arm possesses a second length greater than the first length.

4. The electronic component of claim 1, wherein
a position of a tip of the second protrusion is higher than a position of a tip of the first protrusion in a thickness direction of the board.

5. An electronic component comprising:
a rectangular case including a rectangular opening, the opening being covered with a board;
a first engaging part arranged at least one of parallel side surfaces of the case to each other; and
a second engaging part arranged adjacent to the first engaging part at least one of the side surfaces of the case, wherein
the first engaging part includes a first arm, the first arm includes a first end and a second end, the first end is provided at the case, and the second end includes a first protrusion protruded from the lateral face side of the board toward the surface thereof,
the second engaging part includes a second arm, the second arm includes a third end and a fourth end, the third end is provided at the case, and the fourth end includes a second protrusion protruded from the lateral face side of the board toward the surface thereof, and
a length of the second protrusion in a direction along the surface of the board is greater than a length of the first protrusion.

6. The electronic component of claim 5, further comprising a cover attached to the case and covering the board, the first engaging part and the second engaging part, wherein
a gap is provided between each of the first engaging part and the second engaging part and an inner surface of the cover.

7. The electronic component of claim 5, wherein
the first arm possesses a first length and the second arm possesses a second length greater than the first length.

8. The electronic component of claim 5, wherein
a position of a tip of the second protrusion is higher than a position of a tip of the first protrusion in a thickness direction of the board.
